(19) United States
(12) Patent Application Publication
(10) Pub. No.: US 2013/0222744 A1
(43) Pub. Date: Aug. 29, 2013

(54) PIXEL STRUCTURE AND LIQUID CRYSTAL DISPLAY PANEL THEREOF

(71) Applicants: Meng-Chi Liou, Taoyuan County (TW); Wei-Long Li, Taoyuan County (TW); Ling-Chih Chiu, Hsinchu City (TW)

(72) Inventors: Meng-Chi Liou, Taoyuan County (TW); Wei-Long Li, Taoyuan County (TW); Ling-Chih Chiu, Hsinchu City (TW)

(21) Appl. No.: 13/571,314

(22) Filed: Aug. 9, 2012

(30) Foreign Application Priority Data
Feb. 29, 2012 (TW) 101106498

(51) Int. Cl. H01L 29/786; G02F 1/1335; G02F 1/1343

(52) U.S. Cl. 349/106; 349/138; 257/59; 257/E29.273

(57) ABSTRACT

The present invention provides a pixel structure including a substrate, a common line, a first transparent electrode, an insulating layer, a drain, and a second transparent electrode. The common line is disposed on the substrate, and the first transparent electrode is disposed on the substrate and the common line and electrically connected to the common line. The insulating layer covers the substrate and the first transparent electrode, and the drain is disposed on the insulating layer. The second transparent electrode is disposed on the insulating layer and overlaps the first transparent electrode, and the second transparent electrode is in contact with the drain.

### BACKGROUND OF THE INVENTION

1. Field of the Invention

The present invention relates generally to a pixel structure and a liquid crystal display panel thereof, and more specifically to a pixel structure having transparent storage capacitors and a liquid crystal display panel thereof.

2. Description of the Prior Art

As portable products become popular, the development of liquid crystal display panels with small sizes applied in portable products get much attention. However, as the sizes of the liquid crystal display panels become smaller, the display areas are reduced, so that the aperture ratios of pixels with the same resolution are reduced, thereby decreasing the brightness and the contrast of the products. Or, when the resolution is increased, the aperture ratio of pixels is also reduced, leading to the backlight utilization being reduced. Thus, the brightness of the backlight needs to be enhanced to maintain a similar display brightness, which would increase the power consumption of the backlight modules. It is an extreme limitation for portable products especially as they are intended to have smaller and lighter sizes.

A pixel structure of a conventional liquid crystal display panel includes two scanning lines parallel to each other, two data lines perpendicular to the scanning lines, a thin film transistor disposed at the junction of the scanning lines and the data lines, a common line between the scanning lines and a pixel electrode overlapping part of the scanning lines and the data lines. Since the scanning lines, the data lines, the thin film transistor and the common line are composed of metals, and the storage capacitor is often made of opaque metal layers and transparent pixel electrodes, or made of two opaque metal layers, a part of the light penetrating the liquid crystal display panel is shaded and the aperture ratio of the pixel structure is therefore limited.

In view of the above, how to increase aperture ratios of pixel structures in developing liquid crystal display panels has therefore become an important issue.

### SUMMARY OF THE INVENTION

One of the purposes of the present invention is to provide a pixel structure and a liquid crystal display panel thereof to increase the aperture ratio.

The present invention provides a pixel structure including a substrate, a gate, a common line, a first transparent electrode, a first insulating layer, a semiconductor pattern, a source and a drain, a second transparent electrode, a flat layer and a pixel electrode. The gate is disposed on the substrate, and the common line is disposed on the substrate. The first transparent electrode is disposed on the substrate and the common line, and electrically connects the common line. The first insulating layer covers the substrate, the gate, the common line and the first transparent electrode, and the semiconductor pattern is disposed on the first insulating layer right above the gate. The source and the drain are disposed on the semiconductor pattern and the first insulating layer, and partially overlap the gate respectively. The second transparent electrode is disposed on the first insulating layer, overlaps the first transparent electrode, and the second transparent electrode and the drain contact each other. The flat layer covers the second transparent electrode, the source, the drain and the semiconductor pattern, and the flat layer has a first contact window. The pixel electrode is disposed on the flat layer, and contacts the second transparent electrode through the first contact window.

The present invention provides a liquid crystal display panel including a first substrate, a gate, a common line, a first transparent electrode, a first insulating layer, a semiconductor pattern, a source and a drain, a second transparent electrode, a flat layer, a pixel electrode, a second substrate and a liquid crystal layer. The gate is disposed on the first substrate. The common line is disposed on the first substrate. The first transparent electrode is disposed on the first substrate and the common line, and electrically connects the common line. The first insulating layer covers the first substrate, the gate, the common line and the first transparent electrode. The semiconductor pattern is disposed on the first insulating layer right above the gate. The source and the drain are disposed on the semiconductor pattern and the first insulating layer, and partially overlap the gate respectively. The second transparent electrode is disposed on the first insulating layer, overlaps the first transparent electrode, and the second transparent electrode and the drain contact each other. The flat layer covers the second transparent electrode, the source, the drain and the semiconductor pattern, and the flat layer has a first contact window. The pixel electrode is disposed on the flat layer, and contacts the second transparent electrode through the first contact window. The second substrate and the first substrate are disposed correspondingly, and the liquid crystal layer is disposed between the first substrate and the second substrate.

The present invention forms storage capacitors with the first transparent electrode, the first insulating layer and the second transparent electrode, that all have transparency, so that the areas shaded by lower electrodes of storage capacitors composed of opaque metal materials can be reduced, thereby enhancing the areas of backlight penetrating pixel structures and increasing the aperture ratio of the pixel structures.

These and other objectives of the present invention will no doubt become obvious to those of ordinary skill in the art after reading the following detailed description of the preferred embodiment that is illustrated in the various figures and drawings.

### BRIEF DESCRIPTION OF THE DRAWINGS

FIGS. 1-8 schematically depict manufacturing method diagrams of a pixel structure according to a preferred embodiment of the present invention.

FIG. 9 schematically depicts a cross-sectional view of a pixel structure taken along the line A-A′ of FIG. 8.

FIG. 10 schematically depicts a top view of a liquid crystal display panel according to a preferred embodiment of the present invention.

FIG. 11 schematically depicts a cross-sectional view of a liquid crystal display panel taken along the line B-B′ of FIG. 10.

### DETAILED DESCRIPTION

Specific components are referred by specific words in the specification and claims; however it is known in the art that manufacturers may call the same components with different words. These components are not distinct by their names but by their functions. The word “include or comprise” is an open term. That means it should be known as “include but not limited to”. Moreover, a plurality of preferred embodiments of the present invention paired with drawings is presented later for people in the art to further understand the present invention. It needs to be noted that the drawings are provided for illustrating the present invention, and they are not depicted in original sizes. The words such as “first” and “second” are used to represent different components without restricting their orders.

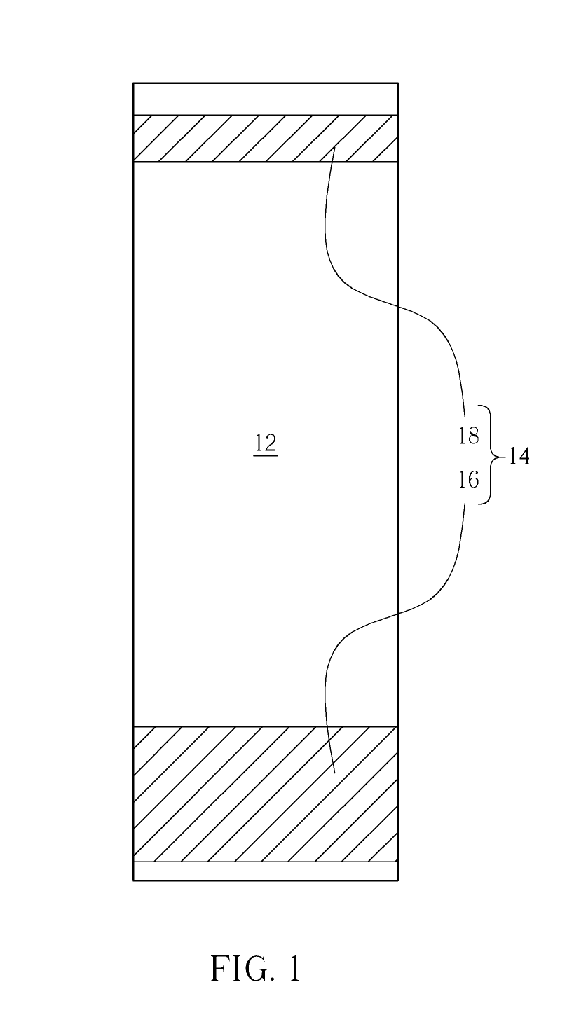

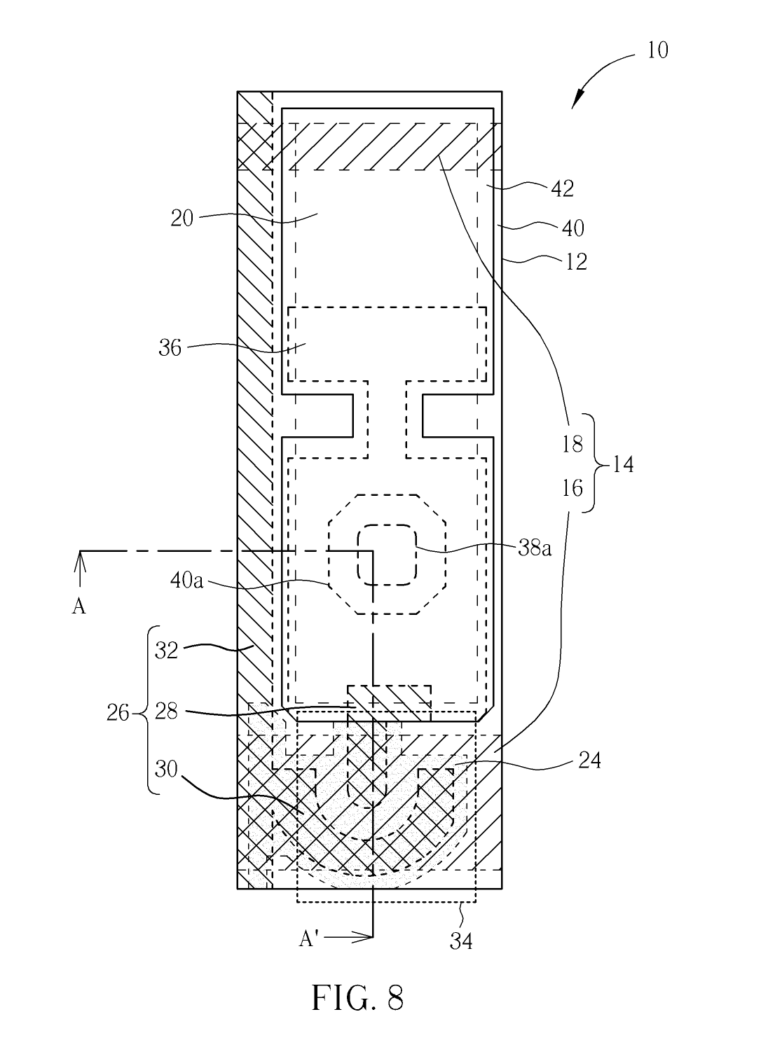

Please refer to FIGS. 1-8, which schematically depict manufacturing method diagrams of a pixel structure according to a preferred embodiment of the present invention, wherein FIG. 8 schematically depicts a top view of a pixel structure according to a preferred embodiment of the present invention. As shown in FIG. 1, a first substrate 12, such as a glass substrate, is provided. A first metal pattern 14 is formed on the first substrate 12. In this embodiment, the method of forming the first metal pattern 14 includes in the following steps. A deposition process is performed to form a first metal layer on the first substrate 12; then, a photolithography and etching process is performed to pattern the first metal layer to form the first metal pattern 14, but it is not limited thereto. The first metal pattern 14 includes a gate 16, a gate line (not shown) and a common line 18, and the gate 16 is a part of the gate line (not shown). The first metal pattern 14 may include metal materials such as at least one, a composite layer of at least two or an alloy of at least two of aluminum (Al), copper (Cu), silver (Ag), chromium (Cr), Titanium (Ti) and molybdenum (Mo), but it is not limited thereto, other conductive materials can be used.

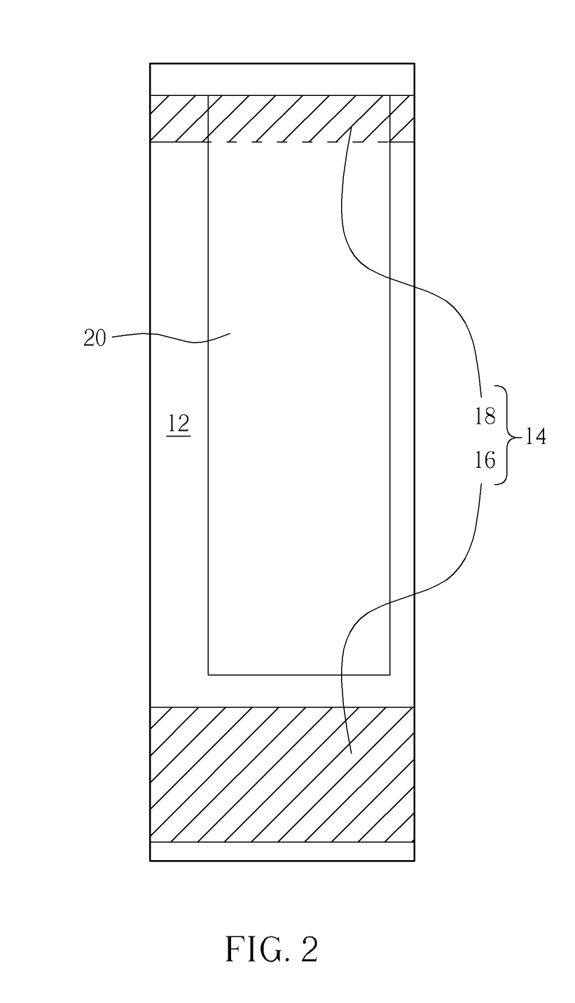

As shown in FIG. 2, a first transparent electrode 20 is formed on the first substrate 12 and the common line 18. In this embodiment, the first transparent electrode 20 contacts and electrically connects the common line 18, and serves as a lower electrode of a storage capacitor. The first transparent electrode 20 does not overlap the gate 16, and does not electrically connect the gate 16. The first transparent electrode 20 may be composed of transparent materials such as indium-tin oxide (ITO), indium-zinc oxide (IZO) or aluminum-zinc oxide (AZO) etc, so that light can penetrate through the first transparent electrode 20.

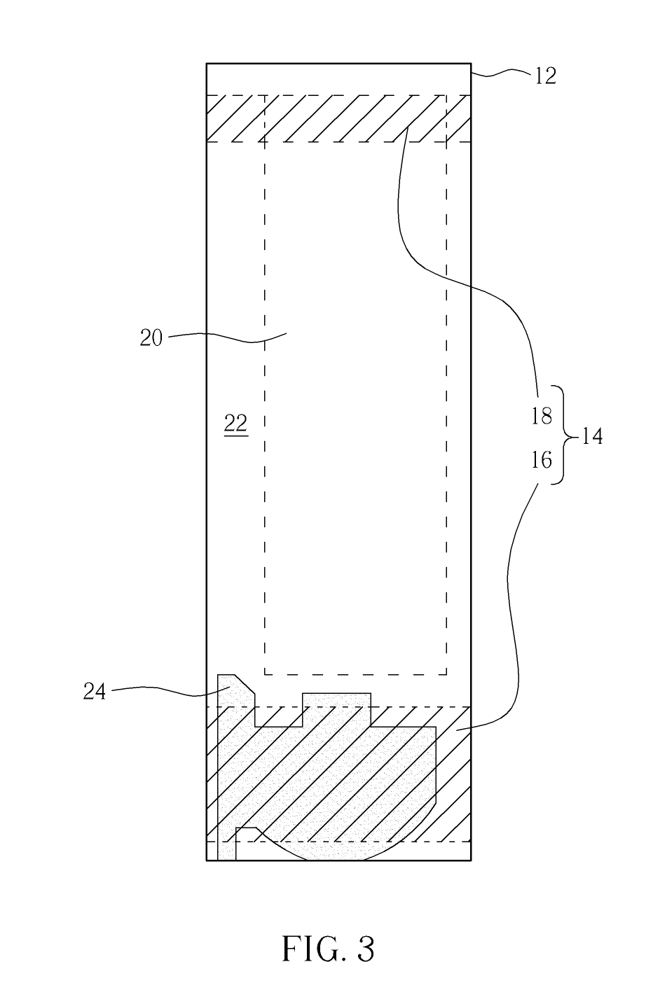

As shown in FIG. 3, a first insulating layer 22 covers the first substrate 12, the gate 16, the common line 18 and the first transparent electrode 20 to serve as a gate insulating layer of a thin film transistor and a dielectric layer of the storage capacitance. A semiconductor pattern 24 is formed on the first insulating layer 22, and the semiconductor pattern 24 overlaps the gate 16 to serve as a channel of the thin film transistor. The semiconductor pattern 24 may include a semiconductor layer and an ohmic contact layer (not shown). The semiconductor layer may be an amorphous silicon semiconductor layer, a poly silicon semiconductor layer, an oxide semiconductor layer or other suitable semiconductor material layers, and the ohmic contact layer may be a non-metal conductive layer such as a doped semiconductor layer.

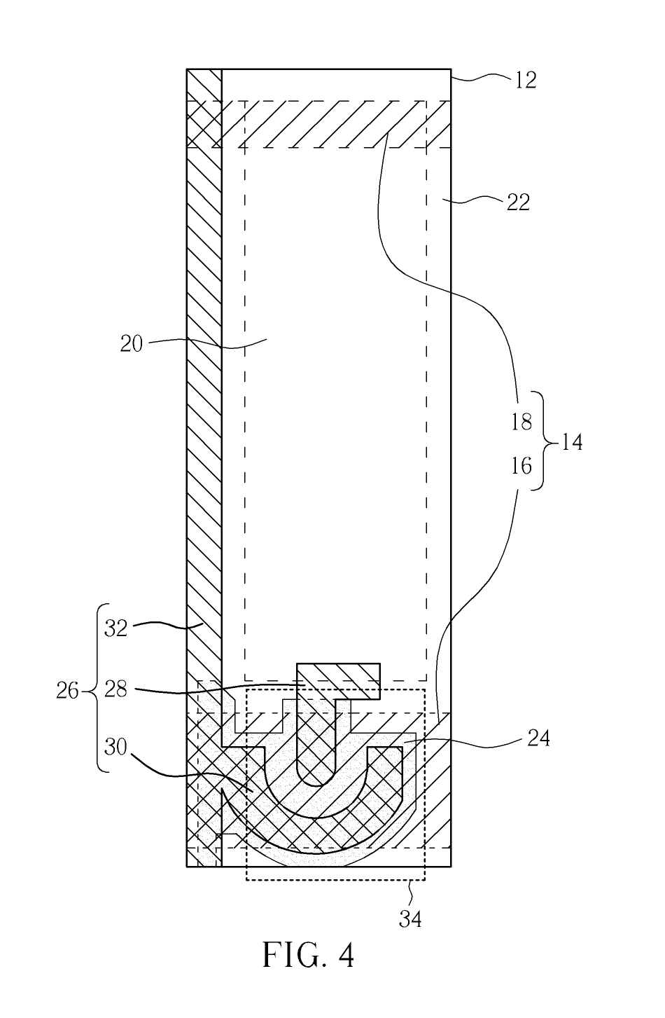

As shown in FIG. 4, a second metal pattern 26 is formed on the semiconductor pattern 24 and the first insulating layer 22. In this embodiment, the method of forming the second metal pattern 26 may include the following steps. Another deposition process may be performed to cover a second metal layer on the semiconductor pattern 24 and the first insulating layer 22; then, another photolithography and etching process is performed to pattern the second metal layer to form the second metal pattern 26. The second metal pattern 26 includes a drain 28, a source 30 and a data line 32, and the source 30 extends out from the data line 32 and electrically connects the data line 32. The drain 28 and the source 30 respectively and partially overlap the gate 16. Thus, the drain 28, the source 30, the gate 16, the semiconductor pattern 24 and the first insulating layer 22 constitute a thin film transistor 34. The second metal pattern 26 may include at least one, a composite layer of at least two or an alloy of at least two of aluminum (Al), copper (Cu), silver (Ag), chromium (Cr), Titanium (Ti) and molybdenum (Mo), but it is not limited thereto, other conductive materials may be used.

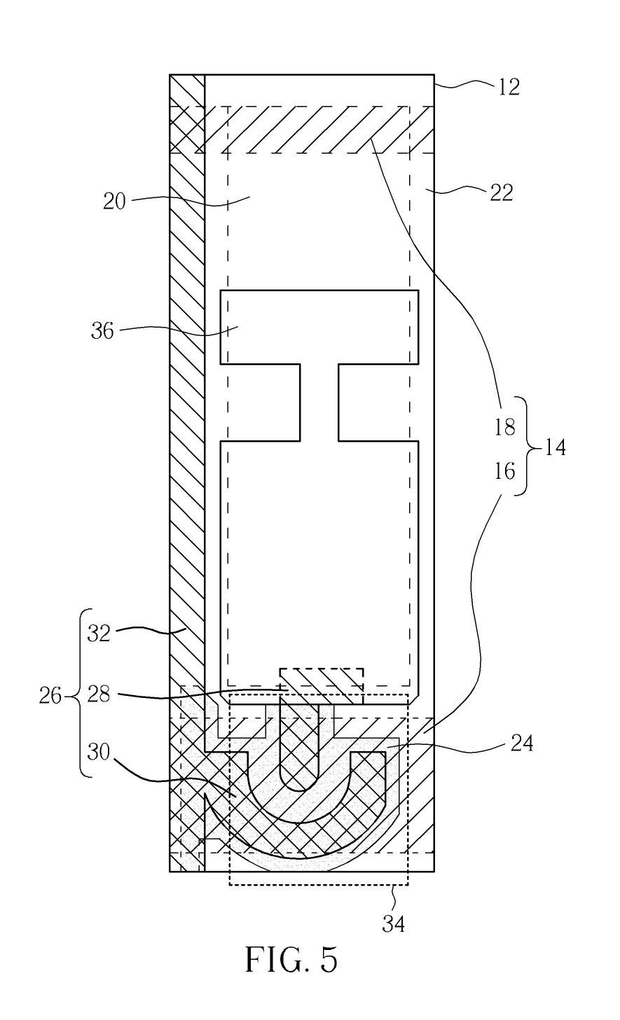

As shown in FIG. 5, a second transparent electrode 36 is formed on the first insulating layer 22 and the drain 28, and the second transparent electrode 36 overlaps the first transparent electrode 20. Accordingly, the second transparent electrode 36 can be used as an upper electrode of the storage capacitor, and the first transparent electrode 20, the first insulating layer 22 and the second transparent electrode 36 constitute the storage capacitor. In this embodiment, the second transparent electrode 36 contacts and electrically connects the drain 28. The second transparent electrode 36 may be composed of transparent materials such as indium-tin oxide (ITO), indium-zinc oxide (IZO) or aluminum-zinc oxide (AZO) etc, so that light can penetrate through the second transparent electrode 36.

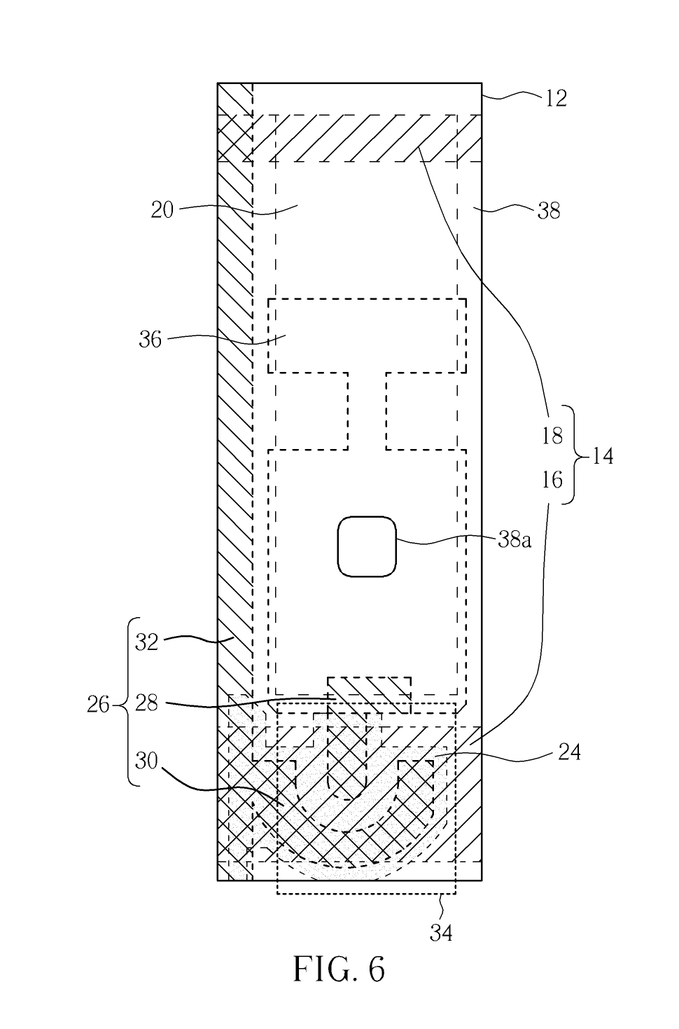

As shown in FIG. 6, a second insulating layer 38 covers the second transparent electrode 36, the thin film transistor 34 and the data line 32. Another photolithography and etching process is performed to form a second contact window 38a in the second insulating layer 38 and expose the second transparent electrode 36. The second insulating layer 38 may be composed of insulating materials such as silicon nitride, silicon oxynitride or silicon oxide for stop vapor from invading the thin film transistor 34, the data line 32 or gate line, thereby preventing the electrical performances of the thin film transistor 34 from being affected by the vapor.

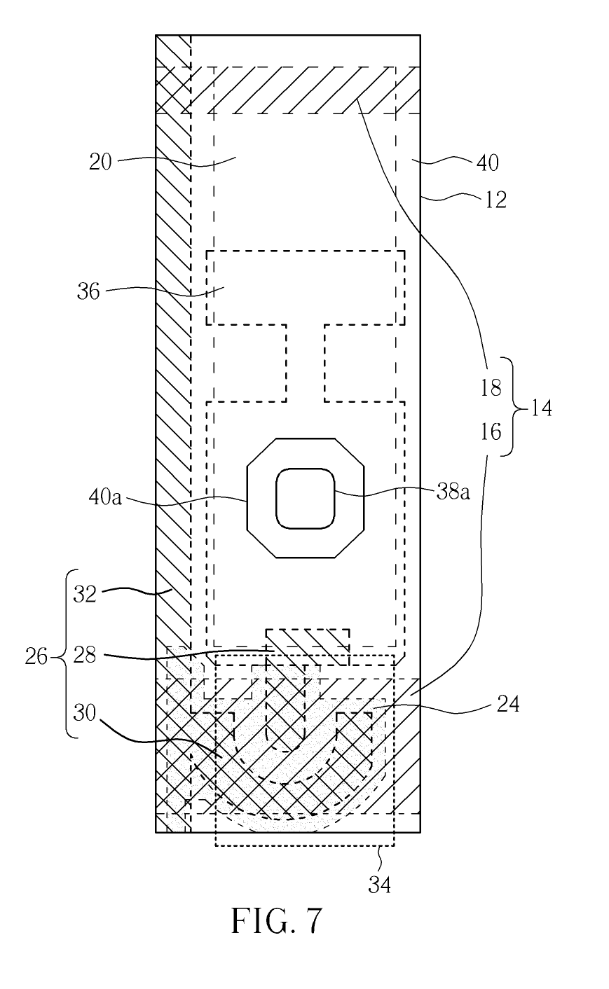

As shown in FIG. 7, a flat layer 40 covers the second insulating layer 38. Another photolithography and etching process is performed to form a first contact window 40a overlapping the second contact window 38a in the flat layer 40, and to remove the flat layer 40 in the second contact window 38a so as to expose the second transparent electrode 36. The flat layer 40 may be composed of organic insulating materials such as photoresist materials to ensure the top surface of the flat layer 40 to be a flat surface.

As shown in FIG. 8, a pixel electrode 42 is formed on the flat layer 40 and the pixel electrode 42 extends from the sidewalls of the first contact window 40a and the second contact window 38a to cover and contact the second transparent electrode 36. Accordingly, the pixel electrode 42 can electrically connect the second transparent electrode 36 and electrically connect the drain 28 through the second transparent electrode 36. Thus, the fabrication of the pixel structure 10 of this embodiment is finished. The pixel electrode 42 may be composed of indium-tin oxide (ITO), indium-zinc oxide (IZO) or aluminum-zinc oxide (AZO) etc, so that light can penetrate through the pixel electrode 42.

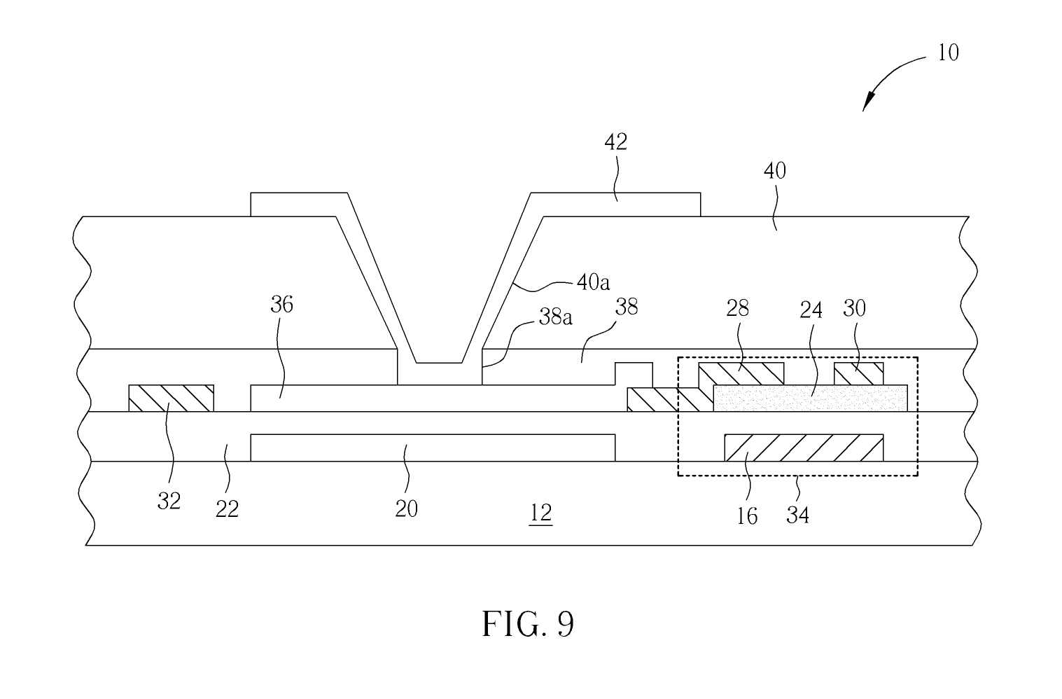

The pixel structure of this embodiment is further illustrated as follows. Please refer to FIG. 8 and FIG. 9, and FIG. 9 schematically depicts a cross-sectional view of a pixel structure along the line A-A′ of FIG. 8. As shown in FIGS. 8-9, the pixel structure 10 of this embodiment includes the first substrate 12, the gate 16, the common line 18, the first transparent electrode 20, the first insulating layer 22, the semiconductor pattern 24, the source 30, the drain 28, the second transparent electrode 36, the second insulating layer 38, the flat layer 40 and the pixel electrode 42. The gate 16 and the common line 18 are disposed on the first substrate 12, and the first transparent electrode 20 is disposed on the first substrate 12 and the common line 18 and electrically connects the common line 18. The first insulating layer 22 covers the first substrate 12, the gate 16 and the first transparent electrode 20, and the semiconductor pattern 24 is disposed on the first insulating layer 22 rightly above the gate 16. The source 30 and the drain 28 are disposed on the semiconductor pattern 24 and the first insulating layer 22, and partially overlap the gate 16 respectively. The second transparent electrode 36 is disposed on the first insulating layer 22, overlaps the first transparent electrode 20, and contacts the drain 28. The second insulating layer 38 is disposed on the data line 32, the second transparent electrode 20, the source 30, the drain 28 and the semiconductor pattern 24, and the flat layer 40 covers the second insulating layer 38. The pixel electrode 42 is disposed on the flat layer 40, and contacts the second transparent electrode 36 through the first contact window 40a and the second contact window 38a. In another embodiment, the pixel structure may not include the second insulating layer.

It is worth noting that, the storage capacitor in this embodiment is formed by the first transparent electrode 20, the first insulating layer 22 and the second transparent electrode 36, that all have transparency, so that the areas shaded by the lower electrode of the storage capacitor composed of opaque metal materials can be reduced, thereby enhancing the areas of backlight penetrating the pixel structure 10 and increasing the aperture ratio of the pixel structure 10. Furthermore, in this embodiment, a sidewall of the first contact window 40a is a sloped sidewall enabling the pixel electrode to cover the sidewall of the first contact window 40a efficiently, so the pixel electrode 42 electrically connects the second transparent electrode 36 well.

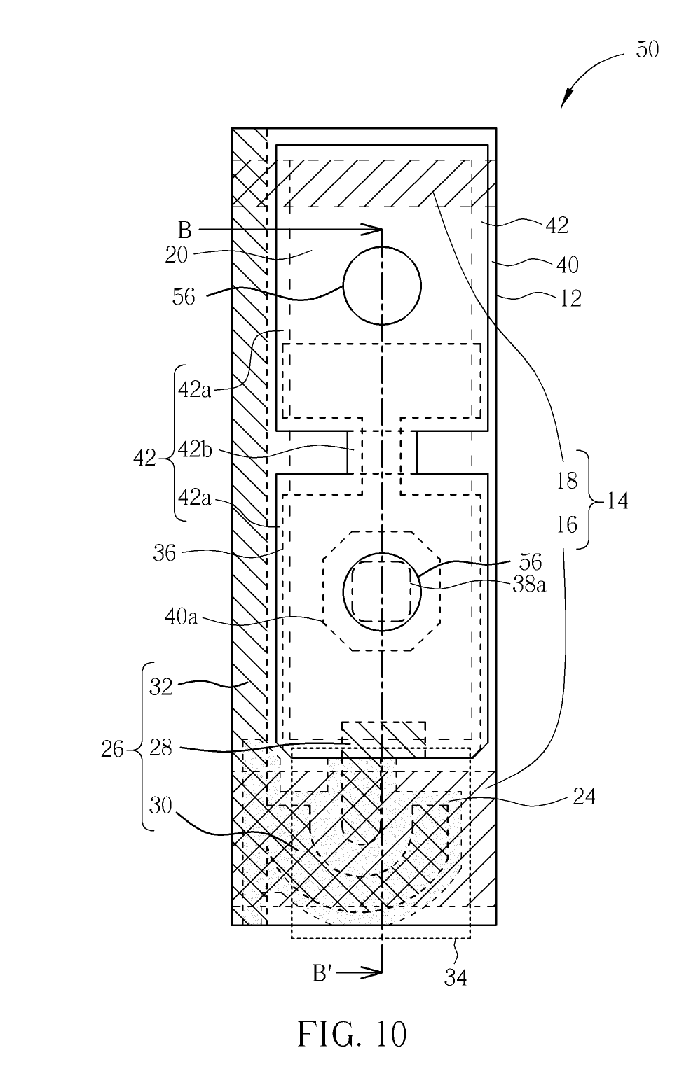

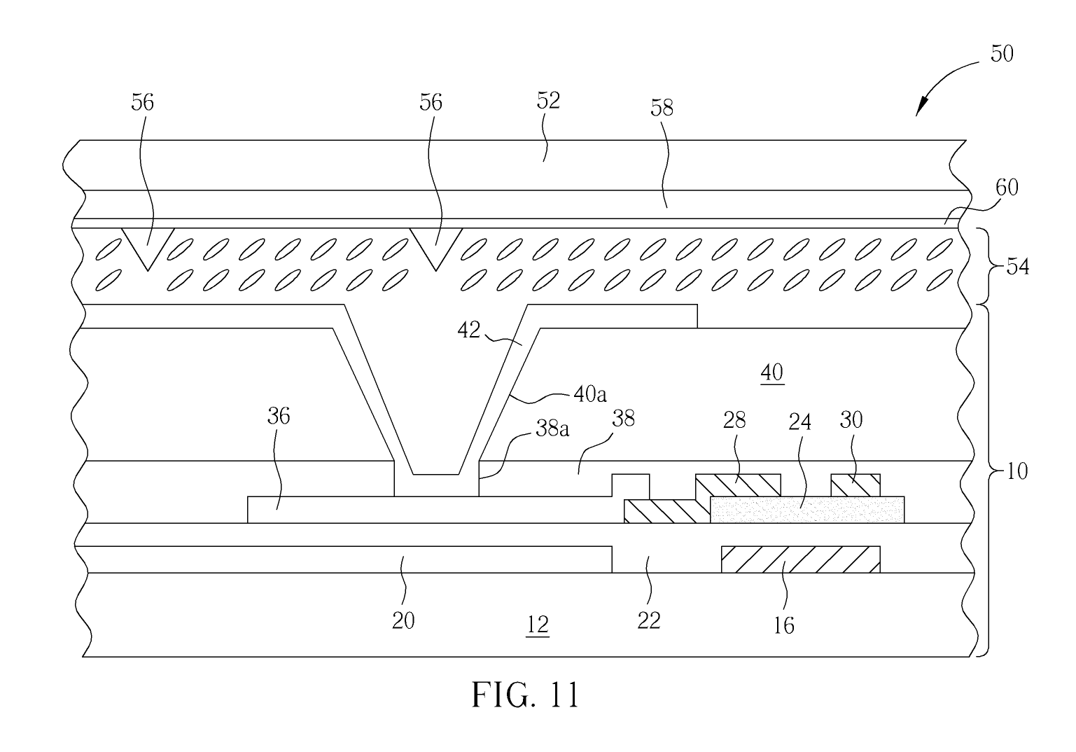

Another liquid crystal display panel is provided in the present invention. Please refer to FIGS. 10-11, wherein FIG. 10 schematically depicts a top view of a liquid crystal display panel according to a preferred embodiment of the present invention, and FIG. 11 schematically depicts a cross-sectional view of a liquid crystal display panel along the line B-B′ of FIG. 10. As shown in FIGS. 10-11, apart from the pixel structure 10 of the above-mentioned embodiment, a liquid crystal display panel 50 of this embodiment includes a second substrate 52, a liquid crystal layer 54, two protrusions 56, a color filter layer 58 and a common electrode layer 60. The second substrate 52 and the first substrate 12 are disposed correspondingly, and the liquid crystal layer 54 is disposed between the first substrate 12 and the second substrate 52. The color filter layer 58 is disposed between the second substrate 52 and the liquid crystal layer 54, and the common electrode layer 60 is disposed between the color filter layer 58 and the liquid crystal layer 54. The protrusions 56 are disposed between the second substrate 52 and the liquid crystal layer 54, and one of the protrusions 56 overlaps the first contact window 40a and the second contact window 38a, meaning that one of the protrusions 56 is disposed correspondingly to the first contact window 40a and the second contact window 38a. In this embodiment, the pixel electrode 42 has two display parts 42a and a bridge part 42b, and the bridge part 42b connects the display parts 42a. Each of the display part 42a respectively overlaps each of the protrusions 56, meaning that each of the protrusions 56 is respectively disposed corresponding to the center of each of the display parts 42a. The pixel electrode 42 disposed on the sidewall of the first contact window 40a and the second contact window 38a is not parallel to the top surface of the flat layer 40, which would limit the grating behavior of the liquid crystal layer 54. Thus, the contrast and the switching rate of the display image are affected. So, the protrusions 56 of this embodiment disposed corresponding to the first contact window 40a and the second contact window 38a can reduce the liquid crystal display panel 40 to display bad image.

To summarize, the present invention forms the storage capacitor by the first transparent electrode, the first insulating layer and the second transparent electrode, that all having transparency, so that the areas shaded by lower electrodes of the storage capacitor composed of opaque metal materials can be reduced, thereby enhancing the areas of backlight penetrating the pixel structure and increasing the aperture ratio of the pixel structure.

Those skilled in the art will readily observe that numerous modifications and alterations of the device and method may be made while retaining the teachings of the invention. Accordingly, the above disclosure should be construed as limited only by the metes and bounds of the appended claims.

What is claimed is:

1. A pixel structure, comprising:
a substrate;
a gate disposed on the substrate;
a common line disposed on the substrate;
a first transparent electrode disposed on the substrate and the common line, that electrically connects the common line;
a first insulating layer covering the substrate, the gate, the common line and the first transparent electrode;
a semiconductor pattern disposed on the first insulating layer right above the gate;
a source and a drain disposed on the semiconductor pattern and the first insulating layer, and partially overlapping the gate respectively;
a second transparent electrode disposed on the first insulating layer and overlapping the first transparent electrode, and the second transparent electrode and the drain contacting each other;
a flat layer covering the second transparent electrode, the source, the drain and the semiconductor pattern, and the flat layer having a first contact window; and
a pixel electrode disposed on the flat layer, and contacting the second transparent electrode through the first contact window.

2. The pixel structure according to claim 1, further comprising:
a second insulating layer disposed between the flat layer and the second transparent electrode, the source, the drain and the semiconductor pattern, and the second insulating layer having a second contact window overlapping the first contact window.

3. The pixel structure according to claim 2, wherein the second insulating layer comprises silicon nitride, silicon oxynitride or silicon oxide.

4. The pixel structure according to claim 1, wherein the flat layer comprises a photoresist material.

5. The pixel structure according to claim 1, wherein the pixel electrode electrically connects the drain by the second transparent electrode.

6. The pixel structure according to claim 1, wherein a sidewall of the first contact window is a sloped sidewall.

7. A liquid crystal display panel, comprising:
a first substrate;
a gate disposed on the first substrate;
a common line disposed on the first substrate;
a first transparent electrode disposed on the first substrate and the common line, that electrically connects the common line;
a first insulating layer covering the first substrate, the gate, the common line and the first transparent electrode;
a semiconductor pattern disposed on the first insulating layer right above the gate;
a source and a drain disposed on the semiconductor pattern and the first insulating layer, and partially overlapping the gate respectively;
a second transparent electrode disposed on the first insulating layer, and overlapping the first transparent electrode, and the second transparent electrode and the drain contacting each other;
a flat layer covering the second transparent electrode, the source, the drain and the semiconductor pattern, and the flat layer having a first contact window;
a pixel electrode disposed on the flat layer, and contacting the second transparent electrode by the first contact window;
a second substrate and the first substrate disposed correspondingly; and
a liquid crystal layer disposed between the first substrate and the second substrate.

8. The liquid crystal display panel according to claim 7, further comprising:
two protrusions disposed between the second substrate and the liquid crystal layer, and one of the protrusions overlapping the first contact window.

9. The liquid crystal display panel according to claim 8, wherein the pixel electrode has two display parts and one bridge part, the bridge part connects the display parts and each of the display parts respectively overlaps each of the protrusions.

10. The liquid crystal display panel according to claim 7, further comprising:
a color filter layer disposed between the second substrate and the liquid crystal layer; and
a common electrode layer disposed between the color filter layer and the liquid crystal layer.

11. The liquid crystal display panel according to claim 7, further comprising:
a second insulating layer disposed between the flat layer and the second transparent electrode, the source, the drain and the semiconductor pattern, and the second insulating layer having a second contact window overlapping the first contact window.

12. The liquid crystal display panel according to claim 11, wherein the second insulating layer comprises silicon nitride, silicon oxynitride or silicon oxide.

13. The liquid crystal display panel according to claim 7, wherein the flat layer comprises a photoresist material.

14. The liquid crystal display panel according to claim 7, wherein the pixel electrode electrically connects the drain through the second transparent electrode.

15. The liquid crystal display panel according to claim 7, wherein a sidewall of the first contact window is a sloped sidewall.
